(19) United States
(12) Patent Application Publication
(10) Pub. No.: US 2026/0130018 A1
(43) Pub. Date: May 7, 2026

(54) LIGHT-EMITTING DIODE AND LIGHT-EMITTING DEVICE

(71) Applicant: QUANZHOU SANAN SEMICONDUCTOR TECHNOLOGY CO., LTD., Quanzhou (CN)

(72) Inventors: Huihuang Huang, Quanzhou (CN); JIN XU, Quanzhou (CN); Fei Liu, Quanzhou (CN); LING-YUAN HONG, Quanzhou (CN); Weida Zhang, Quanzhou (CN); QING WANG, Quanzhou (CN); Cong Li, Quanzhou (CN); Hongquan Guo, Quanzhou (CN)

(21) Appl. No.: 19/377,083

(22) Filed: Nov. 3, 2025

(30) Foreign Application Priority Data
Nov. 4, 2024 (CN) 202411562214.8

(51) Int. Cl. H10H 20/841; H10H 20/831; H10H 29/24

(52) U.S. Cl. CPC H10H 20/841; H10H 20/831; H10H 29/24

(57) ABSTRACT

A light-emitting diode and a light-emitting device are provided. The light-emitting diode includes a semiconductor stack layer, an insulating reflective layer and an electrode structure. The insulating reflective layer defines a first opening and a second opening therein. A second electrode in the electrode structure includes a second connection electrode. In a direction gradually far away from the insulating reflective layer, the second connection electrode at least includes a transparent adhesive layer and a reflective layer located above the transparent adhesive layer. The transparent adhesive layer is a transparent material layer. The transparent adhesive layer can be a same material layer as a current spreading layer above a second semiconductor layer, thus, the transparent adhesive layer can form good adhesion with the current spreading layer. The reflective layer includes an Ag layer with high reflectivity, which can play a reflective role, thereby increasing light output of the light-emitting diode.

### CROSS-REFERENCE TO RELATED APPLICATION

This application claims priority to Chinese Patent Application No. 202411562214.8, filed on Nov. 4, 2024, which is herein incorporated by reference in its entirety.

TECHNICAL FIELD The disclosure relates to the technical field of semiconductors, and more particularly to a light-emitting diode and a light-emitting device.

### BACKGROUND

Light-emitting diodes (LEDs) are widely used in various fields such as display devices, vehicle lamps, and general lighting due to features of high reliability, long lifespan, and low power consumption. Gallium nitride (GaN)-based flip-chip LEDs are increasingly favored by the market due to advantages such as good heat dissipation, high luminous efficiency, and excellent stability.

During chip fabrication, a contact electrode (PAD1) is typically formed after deposition of indium tin oxide (ITO) to establish good ohmic contact with the ITO. This process increases the complexity of the fabrication steps and raises costs. In order to reduce the chip costs, simplified flip-chips have become a focus of further research.

In the fabrication of simplified flip-chips, a distributed Bragg reflector (DBR) layer is often directly deposited over the ITO. This not only enhances the effective reflectivity of the DBR but also omits the need for PAD1 fabrication, thereby reducing costs. After depositing the DBR, vias are etched for electrode connection. These electrodes can utilize metal materials with high reflectivity combined with the DBR to form an omnidirectional reflector (ODR) structure with improved reflection; or they can use metal materials with good adhesion to form good ohmic contact with the ITO. However, there is no single electrode that fulfills both of these requirements: 1. forming good ohmic contact with ITO; and 2. combining with the DBR to form an effective ODR structure that enhances light reflection. Consequently, electrode structures of the light-emitting diodes in the related art negatively impact the brightness and voltage characteristics of the chip.

### SUMMARY

In view of defects and disadvantages of flip-chip light-emitting diode in the related art, a purpose of the disclosure is to provide a light-emitting diode and a light-emitting device. After covering an insulating reflective layer above a semiconductor stack layer, a second connection electrode is first formed in an opening of the insulating reflective layer to increase light reflection at the opening of the insulating reflective layer and improve light output effect of the light-emitting diode.

In order to achieve the above purpose and other relative purposes, in the first aspect, the disclosure provides a light-emitting diode, including a semiconductor stack layer, an insulating reflective layer and an electrode structure. The semiconductor stack layer includes a first semiconductor layer, an active layer and a second semiconductor layer sequentially stacked in that order. The insulating reflective layer is located on a side of the second semiconductor layer, and at least covers a surface of the semiconductor stack layer. The insulating reflective layer defines a first opening and a second opening therein, the first opening is located above the first semiconductor layer, the second opening is located above the second semiconductor layer, and a thickness of the insulating reflective layer is in a range of 2 microns (μm) to 6 μm. The electrode structure is located above the insulating reflective layer. The electrode structure includes a first electrode electrically connected to the first semiconductor layer, and a second electrode electrically connected to the second semiconductor layer. The second electrode includes a second connection electrode, the second connection electrode is filled in the second opening and covers a part of the insulating reflective layer located above the second semiconductor layer. In a direction gradually far away from the insulating reflective layer, the second connection electrode at least includes a transparent adhesive layer and a reflective layer located above the transparent adhesive layer.

In the second aspect, the disclosure provides a light-emitting device, including a circuit board and multiple light-emitting units located on the substrate, and each of the multiple light-emitting units includes the light-emitting diode provided by the disclosure.

As described above, the light-emitting diode and the light-emitting device provided by the disclosure have at least the following beneficial technical effects.

The light-emitting diode of the disclosure includes the semiconductor stack layer, the insulating reflective layer and the electrode structure. The insulating reflective layer defines the first opening and the second opening therein. The second electrode in the electrode structure includes the second connection electrode, and the second connection electrode is filled in the second opening of the insulating reflective layer and is electrically connected to the second semiconductor layer of the semiconductor stack layer. In the direction gradually far away from the insulating reflective layer, the second connection electrode at least includes the transparent adhesive layer and the reflective layer located above the transparent adhesive layer. The transparent adhesive layer is a transparent material layer, in an embodiment, the transparent adhesive layer can be a same material layer as the current spreading layer above the second semiconductor layer, thus, the transparent adhesive layer can form good adhesion with the current spreading layer. The reflective layer includes a silver (Ag) layer and/or an aluminum (Al) layer with high reflectivity, which can play a reflective role, thereby increasing the light output effect of the light-emitting diode. Meanwhile, the reflective layer can form a good ohmic contact with the transparent adhesive layer and the current spreading layer, thereby improving the electrical performance of the light-emitting diode. The second connection electrode can form a good ODR structure with the insulating reflective layer, thereby increasing the reflection effect and improving the optical performance of the light-emitting diode.

On the other hand, the first electrode may include a first contact electrode formed above the first semiconductor layer and a first connection electrode. The first connection electrode is filled in the first opening in the insulating reflective layer and is connected to the first contact electrode. The first contact electrode can serve as an etching stop layer when etching the insulating reflective layer to form the first opening, thereby ensuring etching accuracy and preventing damage to the first semiconductor layer due to over etching.

### BRIEF DESCRIPTION OF DRAWINGS

FIG. 1 illustrates a schematic structural diagram of a light-emitting diode according to an embodiment 1 of the disclosure.

FIG. 2 illustrates a partially enlarged structural diagram at a second connection electrode in FIG. 1.

FIG. 3 illustrates a scanning electron micrograph (SEM) at the second connection electrode in FIG. 1.

FIG. 4 illustrates a schematic top view of a semiconductor stack layer as viewed from the second connection electrode illustrated in FIG. 1.

FIG. 5 illustrates a schematic structural diagram of a light-emitting diode according to an embodiment 2 of the disclosure.

FIG. 6 illustrates a schematic structural diagram of a light-emitting diode according to an embodiment 3 of the disclosure.

FIG. 7 illustrates a schematic structural diagram of a light-emitting diode according to an embodiment 4 of the disclosure.

FIG. 8 illustrates a schematic structural diagram of a light-emitting diode according to an embodiment 5 of the disclosure.

FIG. 9 illustrates a schematic structural diagram of a light-emitting diode according to the embodiment 5 of the disclosure.

FIG. 10 illustrates a schematic structural diagram of a light-emitting diode according to an embodiment 6 of the disclosure.

FIG. 11 illustrates a schematic structural diagram of a light-emitting diode according to an embodiment 7 of the disclosure.

FIG. 12 illustrates a comparison diagram of reflectivity of the light-emitting diode in FIG. 10 and a light-emitting diode in the related art.

FIG. 13 illustrates a schematic structural diagram of a light-emitting device according to an embodiment 8 of the disclosure.

### DESCRIPTION OF REFERENCE SIGNS

100—substrate; 200—semiconductor stack layer; 201—first semiconductor layer; 202—active layer; 203—second semiconductor layer; 204—current spreading layer; 205—current barrier layer; 300—insulating reflective layer; 301—first opening; 302—second opening; 3021—first section; 3022—second section; 3023—platform structure; 400—first electrode; 401—first contact electrode; 402—first connection electrode; 500—second electrode; 501—second connection electrode; 5011—contact layer; 5012—connection layer; 5013—transparent adhesive layer; 5014—reflecttive layer; 502—second contact electrode; 601—first insulating protective layer; 602—second insulating protective layer; 6021—aluminum oxide (Al₂O₃) layer; 6022—silicon oxide (SiO₂) layer; 603—third insulating protective layer; 700—pad electrode; 701—first pad; 702—second pad;
900—light-emitting device; 901—circuit board; 902—light-emitting unit; 903—circuit layer; 904—housing; 905—pad.

### DETAILED DESCRIPTION OF EMBODIMENTS

Embodiments of the disclosure are described below through specific examples, and those skilled in the art can easily understand other advantages and effects of the disclosure from the content disclosed in this specification. The disclosure can also be implemented or applied through different specific embodiments, and various details in this specification can be modified or changed based on different perspectives and applications without departing from a spirit of the disclosure.

It should be noted that the illustrations provided in the embodiments only illustrate a basic concept of the disclosure in a schematic manner. Although the illustrations only show components related to the disclosure and are not drawn according to the number, shape, and size of the components in actual implementation, the form, number, positional relationship, and proportion of each component in actual implementation can be freely changed under the premise of implementing our technical solution, and the component layout may also be more complex.

### Embodiment 1

The disclosure provides a light-emitting diode, as shown in FIG. 1, the light-emitting diode of the embodiment includes a semiconductor stack layer 200, an insulating reflective layer 300 located above the semiconductor stack layer 200, and an electrode structure located above the insulating reflective layer 300. In an optional embodiment, the light-emitting diode further includes a substrate 100, and a material of the substrate 100 can be sapphire, silicon carbide (SiC), silicon (Si) or gallium nitride (GaN). In the embodiment, for example, the substrate 100 is a sapphire substrate.

Also referring to FIG. 1, the semiconductor stack layer 200 is located above the substrate 100, and includes a first semiconductor layer 201, an active layer 202 and a second semiconductive layer 203 sequentially stacked in that order from bottom to top. The first semiconductor layer 201, the active layer 202 and the second semiconductive layer 203 can include III-V nitride semiconductors, for example, nitride semiconductors of A1, gallium (Ga) or indium (In). The first semiconductor layer 201 can include n-type impurities, such as Si, germanium (Ge), and tin (Sn), the second semiconductive layer 203 can include p-type impurities, such as magnesium (Mg), strontium (Sr) and barium (Ba). It can be understood that the doping of the first semiconductor layer 201 and the second semiconductor layer 203 can also be opposite to the above content. The active layer 202 can include a multiple quantum well (MQW) structure, which can emit a desired wavelength by adjusting a composition ratio of nitride semiconductors.

The semiconductor stack layer 200 has a mesa structure to expose a part of a surface of the first semiconductor layer 201, which facilitates the subsequent formation of the electrode structure. A shape of the part of the surface of the first semiconductor layer 201 exposed by the mesa structure of the semiconductor stack layer 200 can be arbitrary, and the mesa structure can be an open mesa structure or a closed mesa structure with a hole structure.

Also referring to FIG. 1, the insulating reflective layer 300 is located above the semiconductor stack layer 200, that is, the insulating reflective layer 300 is located on a side of the second semiconductor layer 203 of the semiconductor stack layer 200, and at least covers the surface of the semiconductor stack layer 200. In the embodiment, the insulating reflective layer 300 covers the surface and sidewalls of the semiconductor stack layer 200. In an embodiment, the insulating reflective layer 300 covers from the sidewalls of the semiconductor stack layer 200 to an exposed surface of the substrate 100. The insulating reflective layer 300 protects the semiconductor stack layer 200 from damage caused by external water vapor or pollutants, thereby ensuring good optical and electrical performance of the light-emitting diode. Optionally, the insulating reflective layer 300 can be a single-layer structure with a refractive index smaller than that of the semiconductor stack layer 200, which can reflect the light emitted from the semiconductor stack layer 200, for example, the insulating reflective layer 300 may be a SiO₂ layer, or a silicon nitride (SiNₓ) layer. Alternatively, the insulating reflective layer 300 can be a multi-layer structure, such as a two-layer combination of SiO₂ layer and SiNₓ layer, or a DBR structure formed by alternately stacking two layers of materials with different refractive indices, for example, a DBR structure formed by alternately stacking any one of titanium oxide (TiO₂), niobium oxide (Nb₂O₅), tantalum oxide (Ta₂O₅), hafnium oxide (HfO₂), zirconium oxide (ZrO₂), and zinc oxide (ZnO) with any one of SiO₂, magnesium fluoride (MgF₂), Al₂O₃, and silicon nitride oxide (SiON). In an optional embodiment, a thickness of the DBR structure is in a range of 0.2 micron (μm) to 10 μm. In an embodiment, the thickness of the DBR structure is in a range of 0.3 μm to 5 μm, 1 μm to 2 μm, 4 μm to 5 μm, or 2 μm to 6 μm.

As shown in FIG. 1, the insulating reflective layer 300 defines a first opening 301 and a second opening 302 therein. The first opening 301 is located above the exposed first semiconductor layer 201 in the semiconductor stack layer 200, and the second opening 302 is located above the second semiconductor layer 203. The electrode structure of the light-emitting diode is located above the insulating reflective layer 300. The electrode structure includes a first electrode 400 connected to the first semiconductor layer 201 and a second electrode 500 connected to the second semiconductor layer 203. In the embodiment, as shown in FIG. 1, the first electrode 400 includes a first contact electrode 401 and a first connection electrode 402. The first contact electrode 401 is formed above the first semiconductor layer 201 exposed by the mesa structure. The first contact electrode 401 can be a single-layer metal material layer or a multilayer metal material layer, for example, the first contact electrode 401 can be one or any combination of nickel (Ni), gold (Au), chromium (Cr), titanium (Ti), platinum (Pt), palladium (Pd), iridium (Ir), Al, Sn, In, tantalum (Ta), copper (Cu), cobalt (Co), iron (Fe), ruthenium (Ru), zirconium (Zr), tungsten (W), and molybdenum (Mo). In an optional embodiment, the first contact electrode 401 can be an Al, Cr/Al, or Ni/Al structure. The first contact electrode 401 forms good ohmic contact with the first semiconductor layer 201, thereby ensuring good electrical performance of the light-emitting diode. Additionally, during the etching of the insulating reflective layer 300 to form the aforementioned first opening 301, the first contact electrode 401 can serve as an etch stop layer, thereby ensuring the etching precision of the first opening 301 and preventing damage to the first semiconductor layer 201 caused by over-etching. As shown in FIG. 1, the first opening 301 is defined above the first semiconductor layer 201 and a bottom od the first opening 301 exposes the first contact electrode 401. The first connection electrode 402 is filled in the first opening 301 and is connected to the first contact electrode 401 at the bottom of the first opening 301, and the first connection electrode 401 extends over the insulating reflective layer 300 surrounding the first opening 301.

Also referring to FIG. 1, the second electrode 500 includes a second connection electrode 501. The second connection electrode 501 includes a contact layer 5011 and a connection layer 5012. The contact layer 5011 is filled in the second opening 302 and is electrically connected to the second semiconductor layer 203. The connection layer 5012 is formed above the contact layer 5011 and is connected to the contact layer 5011. Optionally, a current spreading layer 204 is also formed between the second semiconductor layer 203 and the insulating reflective layer 300. The current spreading layer 204 is a transparent conductive material layer, such as ITO, indium zinc oxide (IZO), and aluminum-doped zinc oxide transparent conductive glass (AZO). In this case, a bottom of the second opening 302 exposes the current spreading layer 204. The current spreading layer 204 at least covers a part of the surface of the second semiconductor layer 203 to spread current as evenly as possible over the surface of the second semiconductor layer 203, thereby improving the light-emitting effect.

Simultaneously, to prevent current crowding in the second semiconductor layer 203 below the second opening 302, a current barrier layer 205 is disposed between the second semiconductor layer 203 and the current spreading layer 204. The current barrier layer 205 is an insulating material layer, such as SiO₂ and/or SiN material layers. In order to ensure the electrical connection between the current spreading layer 204 and the second semiconductor layer 203, as well as the current spreading effect of the current spreading layer 204, the current barrier layer 205 is formed as a patterned structure, that is, the current barrier layer 205 does not cover the entire second semiconductor layer 203. For example, the current barrier layer 205 is located below the second opening 302, and formed as an island or block structure, and the current spreading layer 204 covers a surface and sidewalls of the current barrier layer 205. When the current barrier layer 205 is located below the second opening 302 and formed as an island or block structure, and when projected onto a plane where the surface of the semiconductor stack layer 200 is located, a projected area of the contact layer 5011 is greater than a projected area of the current barrier layer 205 below the second opening 302, and a projection of the current barrier layer 205 below the second opening 302 is located within a projection of the contact layer 5011. This facilitates the lateral spreading of current from the contact layer 5011 along the current spreading layer 204.

As mentioned above, the current spreading layer 204 is formed between the second semiconductor layer 203 and the insulating reflective layer 300. Therefore, the bottom of the second opening 302 includes the current spreading layer 204, that is, the bottom of the second opening 302 is located at the surface of the current spreading layer 204, or the bottom of the second opening 302 is located within the current spreading layer 204 but does not penetrate through the current spreading layer 204. In an optional embodiment, a thickness of the current spreading layer 204 is in a range of 100 angstroms (Å) to 1200 Å. In an embodiment, the thickness of the current spreading layer 204 is in a range of 100 Å to 300 Å, 300 Å to 500 Å, or 500 Å to 1200 Å. When the bottom of the second opening 302 is located within the current spreading layer 204, that is, when the second opening 302 extends into the current spreading layer 204, a depth of the second opening 302 extending into the current spreading layer 204 is less than or equal to 50 Å. In an embodiment, the depth of the second opening 302 extending into the current spreading layer 204 is in a range of 30 Å to 50 Å, 10 Å to 30 Å, or 0 Å to 10 Å, and it is ensured that the second opening 302 does not penetrate through the current spreading layer 204. The contact layer 5011 is filled in the second opening 302 and is connected to the current spreading layer 204 exposed at the bottom of the second opening 302 to achieve electrical connection with the second semiconductor layer 203.

In the embodiment, the contact layer 5011 of the second connection electrode 501 is formed as a multilayer structure containing an Al layer, such as an Ni/Al/Ti/Pt stack structure or a Cr/Al/Ti/Pt stack structure. As mentioned above, the contact layer 5011 is filled in the second opening 302, the Ni layer or Cr layer therein can increase the adhesion between the contact layer 5011 and the current spreading layer 204, thereby forming good ohmic contact with the current spreading layer 204, and ensuring the electrical performance of the light-emitting diode. Simultaneously, the Al layer in the contact layer 5011 has a reflective effect, which can increase the reflectivity of the contact layer 5011, and helps to compensate for the reflective loss caused by forming the second opening 302 in the insulating reflective layer 300, thereby increasing the reflection of light radiated from the semiconductor stack layer 200 and improving the light-emitting effect of the light-emitting diode.

Also referring to FIG. 1, the connection layer 5012 is formed above the insulating reflective layer 300, covers and connects the contact layer 5011. The connection layer 5012 can be a single-layer metal material layer or a multilayer metal material layer, for example, the connection layer 5012 can be a stack structure of Al, Ti, Ni, Cr, and Pt. The connection layer 5012 includes an Al layer, and a thickness of the Al layer is greater than a thickness of the Al layer in the contact layer 5011. Therefore, the connection layer 5012 has high reflectivity and can form a total reflection structure with the insulating reflective layer 300, thereby increasing the reflection efficiency of light radiated from the semiconductor stack layer 200 and improving light-emitting effect.

As mentioned above, both the contact layer 5011 and the connection layer 5012 can be formed as multilayer structures and both can include an Al layer. In an optional embodiment, a thickness of the contact layer 5011 is defined as T1, a thickness of the Al layer in the contact layer 5011 is defined as T1a, a thickness of the connection layer 5012 is defined as T2, and a thickness of the Al layer in the connection layer 5012 is defined as T2a, where 200 nanometers (nm)≤T1≤500 nm, 1500 nm≤T2≤5000 nm, T1a=(0.1 to 0.6)*T1, T2a=(0.2 to 0.8)*T2, and T1a=(0.1 to 0.5)*T2a. The configuration of the Al layers in the contact layer 5011 and the connection layer 5012, along with the respective thickness settings, imparts good adhesion, good reflective effect, and good conductive effect to the contact layer 5011 and the connection layer 5012.

In another optional embodiment, the connection layer 5012 is a multilayer structure including a transparent conductive layer and an Ag layer. The transparent conductive layer can be the same as or different from the material layer of the current spreading layer 204 formed above the second semiconductor layer 203. For example, the transparent conductive layer and the current spreading layer 204 can be ITO material layers. When projected onto the plane where the surface of the semiconductor stack layer 200 is located, a projection of the transparent conductive layer in the connection layer 5012 does not overlap or intersect with a projection of the contact layer 5011. That is, the transparent conductive layer in the connection layer 5012 is not formed above the contact layer 5011, thereby avoiding an increase in the voltage of the light-emitting diode.

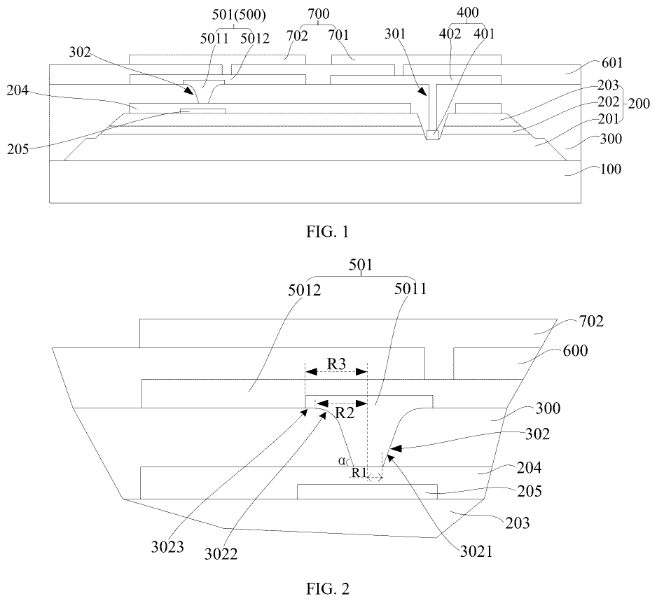

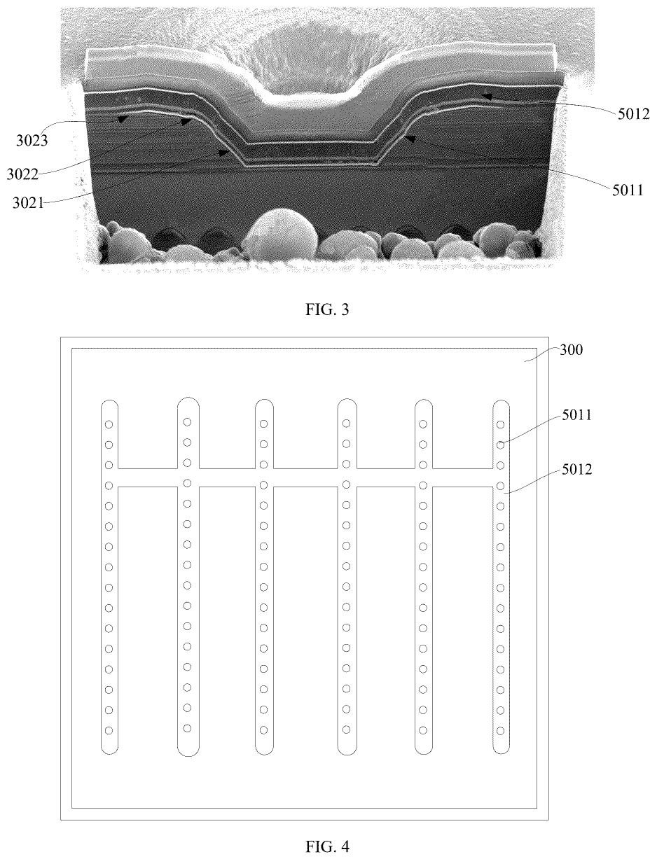

In an optional embodiment, as shown in FIG. 2 and FIG. 3, the contact layer 5011 is filled in the second opening 302 while also extending onto the insulating reflective layer 300 surrounding a periphery of the second opening 302. Specifically, referring to FIG. 3, a sidewall of the second opening 302 includes a first section 3021 and a second section 3022. The insulating reflective layer 300 surrounding the periphery of the second opening 302 defines a platform structure 3023. The first section 3021 forms an inclined sidewall, for example, an included angle α between the first section 3021 and a plane where the current spreading layer 204 at the bottom of the second opening 302 is located is in a range of 40° to 70°. In an embodiment, the included angle α is in a range of 40° to 50°, or 50° to 60°. The second section 3022 is a connecting section between the first section 3021 and the platform structure 3023, which forms a smooth transition section, for example, the second section 3022 can be a rounded corner or an arc-shaped transition section. The contact layer 5011 covers the first section 3021, the second section 3022, and a part of the platform structure 3023, thereby forming a structure similar to a “T” shape.

In an optional embodiment, the second opening 302 is defined as a circular hole with a circular cross-section. A bottom radius of the second opening 302 is defined as R1, and a top opening radius of the second opening 302 is defined as R2. As shown in FIG. 4, the projection of the contact layer 5011 is a circular structure. A radius of the contact layer 5011 is defined as R3, where R2=(1.5 to 3)*R1, R3=(1 to 3)*R1, and R3≥R2. Specifically, the R1 is in a range of 2 μm to 6 μm, for example, around 4 μm. R2 is in a range of 3 μm to 8 μm, for example, around 6 μm. R3 is in a range of 3 μm to 10 μm, for example, around 8 μm. With the aforementioned configuration of the contact layer 5011, a pore size of the second opening 302 can be made smaller to some extent, while simultaneously ensuring good electrical connection between the contact layer 5011 and the second semiconductor layer 203. The contact layer 5011 not only covers the bottom of the second opening 302, the first section 3021 and the second section 3022, but also forms on a part of the platform structure 3023 to increase the reliability of the contact layer 5011 and simultaneously increase a reflective area of the contact layer 5011. The connection layer 5012 covers the contact layer 5011 and also covers a part of the insulating reflective layer 300 around the contact layer 5011, which helps improve the adhesion between the contact layer 5011 and the connection layer 5012. As shown in FIG. 3, in the actual product, the contact layer 5011 can be filled in the second opening 302 well, that is, the contact layer 5011 can uniformly cover the bottom and the sidewalls of the second opening 302, while uniformly extending onto the part of the insulating reflective layer 300 surrounding the periphery of the second opening 302.

In the light-emitting diode, the second opening 302 can be multiple. The connection layer 5012 of the second connection electrode 501 can be formed as a structure connecting the contact layers 5011 at the multiple second openings 302. Since the first opening 301 is defined above the first semiconductor layer 201 exposed by the mesa structure, and to ensure sufficient light-emitting area for the light-emitting diode, a surface area of the mesa structure is usually small. Therefore, typically only one first opening 301 is defined at one mesa structure. FIG. 4 illustrates a schematic diagram of the projection from the second connection electrode 501 towards the semiconductor stack layer 200. It can be seen that a projection area of the connection layer 5012 is greater than a projection area of the contact layer 5011, and the projection of the contact layer 5011 is located within a projection range of the connection layer 5012, thereby ensuring good contact between the connection layer 5012 and the contact layer 5011. Specifically, the connection layer 5012 is connected to the contact layer 5011 at the multiple second openings 302, and the projection area of each part of the connection layer 5012 is greater than a projection area of a corresponding contact layer 5011 connected to the connection layer 5012.

Referring again to FIG. 1, the light-emitting diode of the embodiment further includes a first insulating protective layer 601 and pad electrodes 700. The first insulating protective layer 601 is located above the electrode structure and the insulating reflective layer 300. Specifically, the first insulating protective layer 601 covers the first connection electrode 402 and the second connection electrode 501, as well as an exposed surface of the insulating reflective layer 300. In an embodiment, the first insulating protective layer 601 covers the sidewalls of the insulating reflective layer 300. The first insulating protective layer 601 can be a material layer formed from any one or more of SiO₂, SiN, and Al₂O₃, and can also have the same material layer as the insulating reflective layer 300. The first insulating protective layer 601 provides further insulation and protection against impurities and dust for the light-emitting diode, further ensuring the mutual insulation between the first connection electrode 402 and the second connection electrode 501, while preventing the light-emitting diode from being contaminated or damaged by external dust and moisture.

The pad electrodes 700 are located above the first insulating protective layer 601. The pad electrodes 700 include a first pad 701 and a second pad 702 arranged at intervals. The first pad 701 penetrates through the first insulating protective layer 601 and is connected to the first electrode 400. The second pad 702 penetrates through the first insulating protective layer 601 and is connected to the second electrode 500. Specifically, the first pad 701 is connected to the first connection electrode 402, and the second pad 702 is connected to the second connection electrode 501. The shape and number of the first pad 701 and the second pad 702 can be selected according to actual needs. The pad electrodes 700 can be composed of one or any combination of gold, titanium, platinum, palladium, chromium, aluminum, tin, indium, and copper.

### Embodiment 2

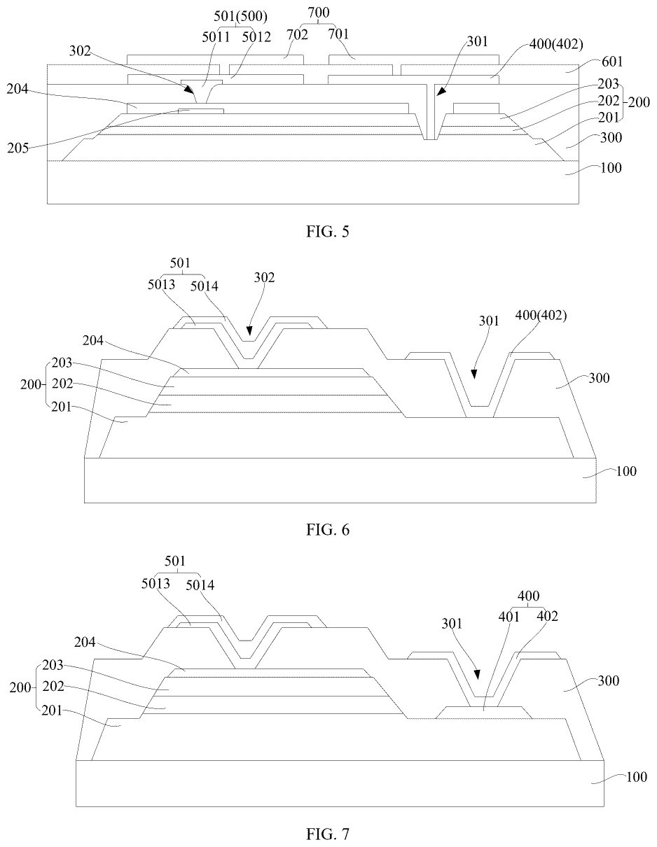

The embodiment also provides a light-emitting diode. As shown in FIG. 5, the light-emitting diode of the embodiment includes a semiconductor stack layer 200, an insulating reflective layer 300 located above the semiconductor stack layer 200, and an electrode structure located above the insulating reflective layer 300. Descriptions identical to those in the embodiment 1 will not be repeated here. The differences are as follows.

As shown in FIG. 5, the light-emitting diode of the embodiment omits the first contact electrode 401 located above the first semiconductor layer 201. The first electrode 400 (or the first connection electrode 402) is directly filled in the first opening 301 and is in direct contact with the first semiconductor layer 201. After omitting the first contact electrode 401, the preparation of the first connection electrode 402 and the second connection electrode 501 can be completed simultaneously in the same process step, thereby reducing the process complexity of the light-emitting diode and helping to lower costs.

### Embodiment 3

The embodiment also provides a light-emitting diode. As shown in FIG. 6, the light-emitting diode of the embodiment includes a semiconductor stack layer 200, an insulating reflective layer 300 located above the semiconductor stack layer 200, and an electrode structure located above the insulating reflective layer 300. Descriptions identical to those in the embodiment 1 or the embodiment 2 will not be repeated here. The differences are as follows.

In the disclosure, the second connection electrode 501 of the second electrode 500 is formed as a multilayer structure. The second connection electrode 501 is filled in the second opening 302 and is electrically connected to the second semiconductor layer 203. In a direction gradually far away from the insulating reflective layer 300, the second connection electrode 501 at least includes a transparent adhesive layer 5013 and a reflective layer 5014 located above the transparent adhesive layer 5013. The transparent adhesive layer 5013 is a material layer capable of forming good contact with the current spreading layer 204 located above the second semiconductor layer 203. In an embodiment, the transparent adhesive layer 5013 is a transparent material layer, such as ITO or indium gallium oxide (IGO). In an embodiment, the transparent adhesive layer 5013 can be the same material layer as the current spreading layer 204 located above the second semiconductor layer 203 to further enhance the adhesion and ohmic contact between the transparent adhesive layer 5013 and the currently spreading layer 204. In an optional embodiment, the current spreading layer 204 is ITO or IGO with a thickness of 100 Å to 500 Å. In an embodiment, the thickness of the current spreading layer 204 is in a range of 100 Å to 300 Å, 200 Å to 400 Å, or 300 Å to 500 Å. The current spreading layer 204 within this thickness range ensures good current spreading effect and good contact with the transparent adhesive layer 5013, while also reducing the absorption of visible light, which is beneficial for improving the light-emitting efficiency of the light-emitting diode. Although not shown in detail in FIG. 6 of the embodiment, it should be understood that a current barrier layer 205 as described in the embodiment 1 is also formed between the current spreading layer 204 and the second semiconductor layer 203.

The reflective layer 5014 of the second connection electrode 501 is a metal material layer with high reflectivity, such as an Ag layer or an Al layer. Optionally, the reflective layer 5014 is an Ag layer. On one hand, the Ag layer has higher reflectivity, which can increase light reflection and improve the light output effect of the light-emitting diode; on the other hand, the Ag layer can have better adhesion with the transparent adhesive layer 5013, thereby enhancing the connection reliability between the Ag layer and the transparent adhesive layer 5013, and improving the stability of the light-emitting diode. In an optional embodiment, a thickness of the transparent adhesive layer 5013 is in a range of 10 Å to 100 Å. In an embodiment, the thickness of the transparent adhesive layer 5013 is in a range of 30 Å to 50 Å. Besides the aforementioned transparent adhesive layer 5013 and the reflective layer 5014, the second connection electrode 501 can also include other metal layers formed above the reflective layer 5014, such as single or multiple layers of Ti, Pt, Ni, and Au.

In an optional embodiment, the insulating reflective layer 300 is a DBR structure. An inductively coupled plasma (ICP) dry etching method is used to etch the insulating reflective layer 300 to form the first opening 301 and the second opening 302. In this process, in order to avoid excessive loss of ITO due to over-etching, the dry etching combines fast etching and slow etching. An etch rate ratio of the DBR to ITO in the final stage is in a range of 300:1 to 50:1. This etching process can ensure that the current spreading layer 204 is not affected or damaged by the etching, thereby allowing the current spreading layer 204 to be made thinner while maintaining good ohmic contact. For example, a thickness of the current spreading layer 204 can be controlled between 100 Å and 300 Å. An etching angle of the DBR is in a range of 40° to 70°. This etching angle ensures good opening characteristics for the first opening 301 and the second opening 302 in the DBR structure, especially for the first opening 301, which is beneficial for subsequent repair of the first semiconductor layer 201 exposed by the first opening 301 after etching, thereby ensuring good optoelectronic performance of the light-emitting diode.

In an optional embodiment, in order to ensure good adhesion between the DBR structure and the current spreading layer 204 and the reflection efficiency of the DBR, a SiO₂ layer is first deposited on the surface of the semiconductor stack layer 200 before forming the aforementioned DBR structure. A thickness of the SiO₂ layer is in a range of 1000 Å to 6000 Å. In the embodiment, the aforementioned DBR structure is formed by alternately stacking TiO₂ and SiO₂, and a thickness of the DBR structure is in a range of 2 μm to 6 μm. A DBR structure with this thickness has good reflectivity, especially at the sidewalls of the first opening 301, where the DBR structure can reflect light radiating to that sidewalls towards the light output surface as much as possible, thereby reducing sidewall light leakage and other light losses at this location.

The aforementioned structure of the second connection electrode 501 can simultaneously satisfy the requirements of forming good ohmic contact with the current spreading layer 204 located above the second semiconductor layer 203 and providing sufficiently high reflection for visible light. The second electrode 500 and the insulating reflective layer 300 in the embodiment form a total reflection structure, which can achieve high reflection across the full visible spectrum and at wide angles, thereby resulting in higher quantum efficiency.

### Embodiment 4

The embodiment also provides a light-emitting diode. As shown in FIG. 7, the light-emitting diode of the embodiment includes a semiconductor stack layer 200, an insulating reflective layer 300 located above the semiconductor stack layer 200, and an electrode structure located above the insulating reflective layer 300. Descriptions identical to those in the embodiment 3 will not be repeated here. The differences are as follows.

As shown in FIG. 7, in the embodiment, the first electrode 400 includes a first contact electrode 401 formed above the first semiconductor layer 201 exposed by the mesa structure, and a first connection electrode 402 located above the insulating reflective layer 300. The first opening 301 exposes the first contact electrode 401, and the first connection electrode 402 is filled in the first opening 301 and is connected to the first contact electrode 401. Optionally, the first contact electrode 401 is a metal capable of forming good ohmic contact with the first semiconductor layer 201, such as Al, Cr/Al, and Ni/Al. In addition to forming good ohmic contact with the first semiconductor layer 201, the first contact electrode 401 can also serve as an etch stop layer. When etching the insulating reflective layer 300 to form the first opening 301, it prevents the etching process from damaging the first semiconductor layer 201 (e.g., N-type GaN). In an embodiment, an opening length of the first opening 301 is less than a bottom length of the first contact electrode 401, while an etching angle of the insulating reflective layer 300 is in a range of 40° to 70°. This further ensures that when etching the insulating reflective layer 300 to form the first opening 301, the bottom of the first opening 301 does not form outside the first contact electrode 401, thereby avoiding etching damage to the first semiconductor layer 201.

### Embodiment 5

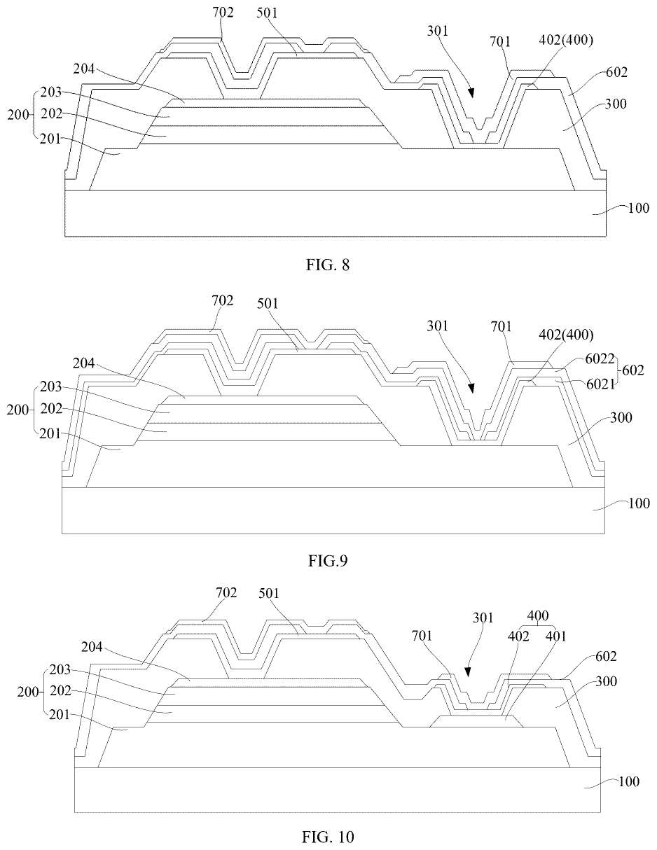

The embodiment also provides a light-emitting diode. As shown in FIG. 8, the light-emitting diode of the embodiment includes a semiconductor stack layer 200, an insulating reflective layer 300 located above the semiconductor stack layer 200, and an electrode structure located above the insulating reflective layer 300. Descriptions identical to those in the embodiment 3 will not be repeated here. The differences are as follows.

As shown in FIG. 8, the light-emitting diode of the embodiment further includes pad electrodes 700. The pad electrodes 700 include a first pad 701 electrically connected to the first electrode 400 of the electrode structure and a second pad 702 electrically connected to the second electrode 500 of the electrode structure. A second insulating protective layer 602 is also formed between the pad electrodes 700 and the electrode structure. Specifically, the second insulating protective layer 602 at least covers surfaces and sidewalls of the first connection electrode 402 and the second connection electrode 501 to block the diffusion of Ag from the second connection electrode 501, thereby ensuring the reflective effect of the second connection electrode 501 and the optoelectronic characteristics of the semiconductor stack layer 200. In an embodiment, the second insulating protective layer 602 covers the surfaces and the sidewalls of the second connection electrode 501 and the first connection electrode 402, as well as the exposed surfaces and sidewalls of the insulating reflective layer 300. As shown in FIG. 9, in a direction from the second connection electrode 501 towards the second pad 702, the second insulating protective layer 602 at least includes sequentially stacked Al₂O₃ layer 6021 and SiO₂ layer 6022 formed by depositing atomic layer. A thickness of the Al₂O₃ layer 6021 formed by depositing atomic layer is in a range of 200 Å to 1000 Å. In an embodiment, the thickness is in a range of 500 Å to 800 Å. A thickness of the SiO₂ layer 6022 is in a range of 1 μm to 3 μm. In an embodiment, the thickness is in a range of 1 μm to 2 μm, or 2 μm to 3 μm. The thickness setting of the second insulating protective layer 602 enables it to effectively prevent the migration of Ag from the second connection electrode 501, while further protecting the light-emitting diode from damage caused by external moisture or contaminants. Additionally, it can absorb as little as possible the light emitted by the semiconductor stack layer 200.

The second insulating protective layer 602 has via holes defined above the first semiconductor layer 201 and the second semiconductor layer 203 to expose the first connection electrode 402 and the second connection electrode 501. The via hole above the first semiconductor layer 201 penetrates through the second insulating protective layer 602 to expose the first connection electrode 402. The via hole above the second semiconductor layer 203 penetrates through the second insulating protective layer 602 to expose the second connection electrode 501. The first pad 701 and the second pad 702 are respectively filled in the via holes and are connected to the first connection electrode 402 and the second connection electrode 501, respectively. The first pad 701 and the second pad 702 are arranged at intervals above the second insulating protective layer 602, and the first pad 701 and the second pad 702 can have the same material composition. Therefore, the first pad 701 and the second pad 702 can be formed in the same deposition step. Optionally, the first pad 701 and the second pad 702 can be Al, Cr/Al, or Ni/Al structural layers.

### Embodiment 6

The embodiment also provides a light-emitting diode. As shown in FIG. 10, the light-emitting diode of the embodiment includes a semiconductor stack layer 200, an insulating reflective layer 300 located above the semiconductor stack layer 200, and an electrode structure located above the insulating reflective layer 300. Descriptions identical to those in the embodiment 5 will not be repeated here. The differences are as follows.

As shown in FIG. 10, the first electrode 400 of the light-emitting diode in the embodiment further includes a first contact electrode 401 formed above the first semiconductor layer 201 exposed by the mesa structure. The first opening 301 exposes the first contact electrode 401, and the first connection electrode 402 is filled in the first opening 301 and is connected to the first contact electrode 401. Optionally, the first contact electrode 401 is a metal capable of forming good ohmic contact with the first semiconductor layer 201, such as Al, Cr/Al, and Ni/Al. In addition to forming good ohmic contact with the first semiconductor layer 201, the first contact electrode 401 can also serve as an etch stop layer. When etching the insulating reflective layer 300 to form the first opening 301, it prevents the etching process from damaging the first semiconductor layer 201 (e.g., N-type GaN). In an embodiment, an opening length of the first opening 301 is less than a bottom length of the first contact electrode 401, while an etching angle of the insulating reflective layer 300 is in a range of 40° to 70°. This further ensures that when etching the insulating reflective layer 300 to form the first opening 301, the bottom of the first opening 301 does not form outside the first contact electrode 401, thereby avoiding etching damage to the first semiconductor layer 201.

### Embodiment 7

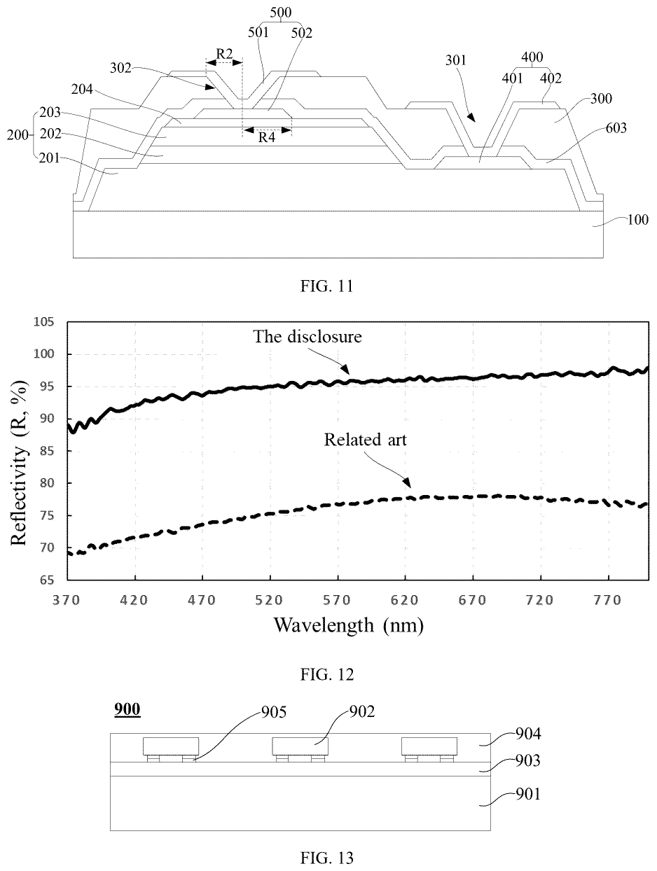

The embodiment also provides a light-emitting diode. As shown in FIG. 11, the light-emitting diode of the embodiment includes a semiconductor stack layer 200, an insulating reflective layer 300 located above the semiconductor stack layer 200, and an electrode structure located above the insulating reflective layer 300. Descriptions identical to those in the embodiment 6 will not be repeated here. The differences are as follows.

The second electrode 500 of the light-emitting diode in the embodiment includes a second connection electrode 501 and a second contact electrode 502. The second contact electrode 502 is located above the second semiconductor layer 203, and the second opening 302 in the insulating reflective layer 300 exposes the second contact electrode 502. The second connection electrode 501 is filled in the second opening 302 and is connected to the second contact electrode 502. In an optional embodiment, a thickness of the second connection electrode 501 is in a range of 3μm to 8 μm. In an embodiment, the thickness of the second connection electrode 501 is in a range of 4 μm to 7 μm, or 4 μm to 6 μm.

Additionally, in the embodiment, a third insulating protective layer 603 is formed between the insulating reflective layer 300 and the semiconductor stack layer 200. The third insulating protective layer 603 at least covers the surfaces and the sidewalls of the first contact electrode 401 and the second contact electrode 502. In an embodiment, the third insulating protective layer 603 covers the surfaces and the sidewalls of the first contact electrode 401 and the second contact electrode 502, and the surfaces and the sidewalls of the semiconductor stack layer 200, and even extends to cover the exposed surface of the substrate 100. The insulating reflective layer 300 is formed above the third insulating protective layer 603. In the embodiment, a thickness of the insulating reflective layer 300 is in a range of 4 μm to 10 μm. The second contact electrode 502 includes an Ag material layer.

In an optional embodiment, the third insulating protective layer 603 at least includes sequentially stacked Al₂O₃ layer and/or SiO₂ layer formed by depositing atomic layer. A thickness of the Al₂O₃ layer is in a range of 200 Å to 1000 Å, and a thickness of the SiO₂ layer is in a range of 1000 Å to 6000 Å. In an embodiment, the thickness of the SiO₂ layer is in a range of 2000 Å to 5000 Å, 1000 Å to 3000 Å, or 3000 Å to 5000 Å. The material selection and thickness setting of the third insulating protective layer 603 enable it to effectively block the diffusion and migration of Ag from the second contact electrode 502, thereby ensuring good reflective effect of the second contact electrode 502 and good optoelectronic performance of the semiconductor epitaxial stack layer.

In order to enhance the reflective effect of the insulating reflective layer 300, in the embodiment, the thickness of the insulating reflective layer 300 is in a range of 1 μm to 10 μm. In an embodiment, the thickness of the insulating reflective layer 300 is in a range of 2 μm to 6 μm. Simultaneously, the thickness of the current spreading layer 204 is in a range of 100 Å to 300 Å. This ensures good current spreading effect while minimizing its light absorption as much as possible, thereby allowing more light to be reflected by the second electrode 500 and the insulating reflective layer 300 to become the output light of the light-emitting diode.

Also as shown in FIG. 11, the third insulating protective layer 603 also defines via holes connected to the first opening 301 and the second opening 302 respectively. The first connection electrode 402 of the first electrode 400 is located above the insulating reflective layer 300, and is filled in the first opening 301 and the via hole in the third insulating protective layer 603 to connect with the first contact electrode 401. The second connection electrode 501 of the second electrode 500 is located above the insulating reflective layer 300, and is filled in the second opening 302 and the via hole in the third insulating protective layer 603 to connect with the second contact electrode 502. The second connection electrode 501 can be an Al layer, or a Cr/Al stack layer, or a Ni/Al stack layer, with a thickness in a range of 3 μm to 8 μm. This thickness setting can enhance the reflective effect.

The second contact electrode 502 should not be too small. When the second contact electrode 502 is too small, overlay errors in the process may cause poor alignment between the second contact electrode 502 and the second opening 302. This could lead to damage of the current spreading layer 204 due to over-etching on one hand, and poor connection reliability between the second connection electrode 501 and the second contact electrode 502 on the other hand, thereby affecting the electrical performance of the light-emitting diode. Similarly, an area of the second contact electrode 502 should not be too large. Since the reflectivity of the DBR is greater than that of the second contact electrode 502, when the area of the second contact electrode 502 is too large, it would reduce the amount of light that can be reflected by the insulating reflective layer 300, thereby affecting the light-emitting efficiency of the light-emitting diode. Therefore, in an optional embodiment, as shown in FIG. 11, a top opening radius of the second opening 302 is R2. A projection of the second contact electrode 502 is defined as circular, and a radius of the second contact electrode 502 is defined as R4, where R4=R2 to (R2+8 μm). As described above, the area of the second contact electrode 502 is controlled to be slightly larger than or equal to the opening size of the second opening 302, to ensure that during the dry etching of the DBR to form the second opening 302, the current spreading layer 204 located below the second contact electrode 502 is protected from being etched, thereby ensuring its integrity and current spreading effect. Simultaneously, it ensures that as much light as possible is reflected by the insulating reflective layer 300, thereby improving the light output efficiency of the light-emitting diode.

As shown in FIG. 12, compared to the related art that Cr/Al material is used as the metal layer in direct contact with the current spreading layer 204, the formation of the second contact electrode 502 increases the reflectivity at the second electrode 500 from less than 75% to over 90%. Especially in a wavelength range of 420 nm to 500 nm, and in a visible light range greater than 520 nm, the reflectivity reaches over 95%. The aforementioned characteristics of the second electrode 500 reduce its light absorption and improve the optical performance of the chip. Meanwhile, the second contact electrode 502 (e.g., Ag) can form good ohmic contact with the current spreading layer 204 on the second semiconductor layer 203, thereby resulting in lower voltage for the light-emitting diode and improved light efficiency.

### Embodiment 8

The embodiment provides a semiconductor light-emitting device. As shown in FIG. 13, the light-emitting device 900 includes a circuit board 901 and multiple light-emitting units 902 electrically connected to the circuit board 901. In the embodiment, each light-emitting unit 902 is the semiconductor light-emitting element (i.e., light-emitting diode) provided in the embodiment 1. Also as shown in FIG. 13, the circuit board 901 has multiple sets of pads 905. The pad electrodes 700 of each light-emitting unit 902 are electrically connected to one set of pads 905. Furthermore, a circuit layer 903 is disposed within the circuit board 901, and the light-emitting units 902 are electrically connected to the circuit layer 903 via the pads 905. As shown in FIG. 13, the light-emitting device 900 can further include a housing 904 to protect the light-emitting units 902 from external contamination or damage, without affecting the light output effect of the light-emitting units 902. The aforementioned configuration of the circuit layer and the pad areas of the light-emitting diode in the disclosure increases the bonding strength when fixed to the aforementioned pads, thereby improving the reliability of the device.

The aforementioned embodiments are merely illustrative of principles and efficacy of the disclosure, and are not intended to limit the disclosure. Those skilled in the art can make modifications or changes to the above embodiments without departing from the spirit and scope of the disclosure. Therefore, all equivalent modifications or changes made by those skilled in the art without departing from the spirit and technical concept disclosed in the disclosure shall still fall within the scope of the claims of the disclosure.

What is claimed is:

1. A light-emitting diode, comprising:
a semiconductor stack layer, comprising a first semiconductor layer, an active layer and a second semiconductor layer sequentially stacked in that order;
an insulating reflective layer, located on a side of the second semiconductor layer, and at least covering a surface of the semiconductor stack layer, wherein the insulating reflective layer defines a first opening and a second opening therein, the first opening is located above the first semiconductor layer, the second opening is located above the second semiconductor layer, and a thickness of the insulating reflective layer is in a range of 2 microns (μm) to 6 μm; and
an electrode structure, located above the insulating reflective layer, wherein the electrode structure comprises a first electrode electrically connected to the first semiconductor layer, and a second electrode electrically connected to the second semiconductor layer; and
wherein the second electrode comprises a second connection electrode, the second connection electrode is filled in the second opening and covers a part of the insulating reflective layer located above the second semiconductor layer; and in a direction facing away from the insulating reflective layer, the second connection electrode at least comprises a transparent adhesive layer and a reflective layer located above the transparent adhesive layer.

2. The light-emitting diode as claimed in claim 1, wherein, at the first opening and the second opening, an included angle between a sidewall of the insulating reflective layer and a plane where the semiconductor stack layer is located is in a range of 40° to 70°.

3. The light-emitting diode as claimed in claim 1, wherein a material layer of the transparent adhesive layer comprises at least one of indium tin oxide (ITO) and indium gallium oxide (IGO).

4. The light-emitting diode as claimed in claim 1, wherein a thickness of the transparent adhesive layer is in a range of 10 angstroms (Å) to 100 Å.

5. The light-emitting diode as claimed in claim 1, wherein a material of the reflective layer comprises silver (Ag).

6. The light-emitting diode as claimed in claim 3, wherein, when projected onto a plane where the surface of the semiconductor stack layer is located, a projection boundary of the second connection electrode is located outside a projection boundary of the second opening.

7. The light-emitting diode as claimed in claim 1, wherein the first electrode is filled in the first opening and is electrically connect to the first semiconductor layer.

8. The light-emitting diode as claimed in claim 7, wherein the first electrode comprises a first contact electrode and a first connection electrode, the first contact electrode is located above the first semiconductor layer, the first opening exposes the first contact electrode, and the first connection electrode is filled in the first electrode and is connected to the first contact electrode.

9. The light-emitting diode as claimed in claim 8, wherein a maximum opening length of the first opening is less than a maximum length of the first contact electrode.

10. The light-emitting diode as claimed in claim 6, further comprising a current spreading layer and a current barrier layer, wherein the current spreading layer is located between the insulating reflective layer and the second semiconductor layer, the current barrier layer is located between the current spreading layer and the second semiconductor layer, the current barrier layer covers a part of the second semiconductor layer, and is at least located below the second opening.

11. The light-emitting diode as claimed in claim 1, further comprising:
a second insulating protective layer, located above the electrode structure and the insulating reflective layer; and
pad electrodes, located above the second insulating protective layer, wherein the pad electrodes comprise a first pad and a second pad arranged at intervals, the first pad penetrates through the second insulating protective layer to connect to the first electrode, and the second pad penetrates through the second insulating protective layer to connect to the second electrode.

12. The light-emitting diode as claimed in claim 11, wherein, in a direction from the second connection electrode to the second pad, the second insulating protective layer at least comprises an aluminum oxide (Al₂O₃) layer and a silicon oxide (SiO₂) layer sequentially stacked in that order.

13. The light-emitting diode as claimed in claim 12, wherein a thickness of the Al₂O₃ layer is in a range of 200 Å to 1000 Å, and a thickness of the SiO₂ layer is in a range of 1 μm to 3 μm.

14. A light-emitting device, comprising a circuit board and a plurality of light-emitting units located on the substrate, and each of the plurality of light-emitting units comprises the light-emitting diode as claimed in claim 1.
